(19) United States
(12) Patent Application Publication
(10) Pub. No.: US 2008/0061235 A1
(43) Pub. Date: Mar. 13, 2008

(54) Detecting Device Based on a Synthetic Diamond

(75) Inventors: Marie-Josephine Guerrero, Saint Maur Des Fosses (FR); Philippe Bergonzo, Massy (FR); Dominique Tromson, Le Plessis-Robinson (FR)

Correspondence Address: PAULEY PETERSEN & ERICKSON, 2800 WEST HIGGINS ROAD, SUITE 365, HOFFMAN ESTATES, IL, 60195, US

(73) Assignee: Commissariat A L'Energie Atomique, Paris (FR)

(21) Appl. No.: 11/661,950

(22) PCT Filed: Sep. 1, 2005
(86) PCT No.: PCT/EP05/54318

§ 371 Date: Mar. 2, 2007

(30) Foreign Application Priority Data
Sep. 3, 2004 (FR) 0409335

(51) Int. Cl. G01T 1/02; B05D 5/12; B21D 39/00; H01G 9/16; C23C 16/27

(52) U.S. Cl. 250/336.1; 204/408; 250/395; 29/428; 422/243; 427/122; 427/249.8

(57) ABSTRACT

A detector that includes a sensing plate formed of a thin synthetic diamond plate is provided. The detector is characterized in that it includes means for heating the sensing plate. The heating means comprises a thin heating plate whose material is essentially constituted of carbon atoms. The invention also relates to a device that includes a detector of the aforementioned type, a measuring method that uses such a detector, and a method for producing this detector.

### BACKGROUND OF THE INVENTION

1. Field of the Invention

The invention relates to detection using synthetic diamond.

More precisely, it relates to radiation and particle detectors, in particular of X, gamma, electron, or proton type.

Detectors of the invention may be used for the metrology and controlling of radiation sources such as particle accelerators used in medicine (radiotherapy, radiology, etc.) and/or radiation sources of synchrotron type for applications such as measuring radiation doses, radiation dose rates, detecting the position, intensity and profile of a beam.

The invention also relates to the manufacture of said detectors.

2. Discussion of Related Art

Natural diamond offers numerous advantages for use in manufacturing radiation detectors meeting specific conditions of use, such as the detection of radiation in a hostile environment or the metrology of X-ray beams. It is a material which resists radiation, acid solutions and high temperatures (<600° C.).

For in-line radiation measurement or metrology, various criteria are also required related to the intended application, such as the possibility to manufacture very thin layers and/or the need for a low atomic number, or to avoid the use of non tissue-equivalent materials in the vicinity of the detector, i.e., a tissue-equivalent material is a material in which the deposited radiation dose is close to the dose deposited in the human body.

Metrology (radiation dose, beam profile) on medical accelerators is undergoing full expansion, and it is desired to measure radiation dose and beam-line dose rate with a tissue-equivalent material. The assessed potential of diamond in this area has shown the possibility of producing miniature dosimeters which can be used, for example, for mapping measurement and for point dose measurement.

Similarly, for the metrology of X-ray beams and synchrotron light sources in particular, it is desired to insert in the line of light, and permanently, a thin non-disturbing device to measure the intensity, position and profile of the light beam.

The use of natural diamond crystals as detectors is known, in particular for medical radiotherapy. These devices have numerous advantages.

Diamond has high mechanical resistance and also resists against corrosive environments and at very high radiation doses.

Diamond, consisting of carbon atoms, is a material that is scarcely harmful for the human body, and can have advantages of biocompatibility and resistance to biomedical environments.

The low atomic number Z of diamond (Z=6) allows its use for the measurement of irradiating beams with no significant or total absorption. Diamond can therefore be used for “in-line” metrology. In the remainder of this description, a material will be said to have a low Z when its atomic number is 8 or less.

The atomic number of diamond is close to the equivalent atomic number of human tissue (7.42 for muscles, 5.94 for fat, i.e., an average of approximately 7), and the radiotherapy dose measured by a diamond detector can easily be related to the dose received by a patient: diamond is a tissue-equivalent material.

Prior art detectors are of small size which is an advantage for new radiotherapy treatments (IMRT).

Previous detectors have disadvantages however.

Their manufacture is unitary, i.e., each sample of natural diamond must be pre-selected to obtain gems of adequate properties for medical dosimetry measurements. Each gem allows the manufacture of a single detector, the small size of natural samples not allowing several devices to be produced having identical characteristics. Each detector must be individually calibrated and gauged.

As a result, the cost of such detectors is prohibitive.

In addition, it is not easy to guarantee supplies of natural diamond whose properties meet specifications.

Finally the performance of devices of natural diamond often can only be guaranteed if the detectors are pre-treated (e.g., by daily pre-irradiation). This step adds an additional cost due to irradiation time and unavailability of the equipment during this pre-treatment time.

To address these disadvantages, it has been proposed in the prior art to use synthetic diamond to manufacture detectors.

It is possible to effectively produce synthetic diamond. The Chemical Vapor Deposition (CVD) synthesis technique, generally used by those skilled in the art, is suitable for achieving the manufacture of a material having the desired performance characteristics for radiation detection.

Synthesis brings a reduction in the cost of detectors, due to high production yields.

Synthetic diamond can be produced on a large surface area and in series. Typically, samples can be synthesized over a diameter of several centimeters.

It is also possible to manufacture detectors in relation to demand, which allows optimization of electric performance with respect to the desired application.

Finally, a mosaic of detectors can be produced having identical characteristics for imaging and/or the integration of the devices in other equipment.

Unfortunately, current synthetic diamond production techniques only allow the easy manufacture of a low cost, polycrystalline material.

However, characterizations of synthetic diamond made by CVD on a substrate other than diamond have shown that end limitations regarding the improvement of detectors are related to the method of manufacture of the diamond, and derive from the polycrystalline nature of the material.

Electric defects are identified, and may be due to the non-homogeneous structure of the material (grains and grain boundaries) but also to the presence of impurities in low concentration.

These characteristics of synthetic diamond involve phenomena of trapping and de-trapping of charge carriers when using the detector. These phenomena are responsible for the change in sensitivity of the detectors over time.

Characterization techniques, routinely used to study the concentrations of defects in synthetic diamond, have made it possible to classify the electric defects into several categories. Each trap can be defined by a level of energy in the bandgap of the diamond. Modification of the charge status of this energy level (by de-trapping and trapping) in relation to the thermal energy of the detector is used to define this energy level:

the trap levels for which the thermal energy required for de-trapping is less than the energy corresponding to ambient temperature. The carriers responsible for the electric signal under irradiation can be captured at these levels at ambient temperature and are released near-instantly by thermal activation. This trap level can therefore be considered as “stable” or inactive when the device is used at ambient temperature;

deep trap levels for which thermal energy required for de-trapping is very high compared with the energy corresponding to ambient temperature (temperature >200° C.). Under irradiation, these levels will gradually be “occupied” until they reach saturation, the thermal energy at ambient temperature then being insufficient to induce a de-trapping phenomenon. The generated carriers are no longer disturbed and transit freely within the material. This translates as a stable behavior of the detector under irradiation when used at ambient temperature. The contribution of these trap levels has long been commented upon with respect to diamond, since their occupancy contributes to a gradual increase in the sensitivity of the detector. This gradual occupancy step of deep traps is known in the literature as “pumping” or “priming”; and

shallow trap levels, for which the thermal energy required for de-trapping is close to the energy corresponding to ambient temperature. These levels limit the use of diamond detectors in industrial applications. The closeness of the thermal activation temperature of the trap levels with respect to ambient temperature contributes towards gradual de-trapping of the carriers at these levels, with time constants possibly reaching several minutes according to detector. Therefore, when the use of a device is stopped for a few moments, hence its radiation, a transitory phenomenon is observed when it is re-used. This phenomenon is highly restrictive since it means that the user must have knowledge of the prior use of the device under irradiation, so that its detection behavior can be interpreted. Time constants are then in the order of a few seconds to a few hours, and can therefore interfere with daily use of an industrial device.

Consequently, the electric and detection performance characteristics of synthetic diamond detectors are generally less than those of a natural material subjected to drastic selection criteria. The reproducibility of measurement may be affected, the response times may be longer and the characteristics of detection non-linear.

### SUMMARY OF THE INVENTION

The invention seeks to overcome these disadvantages without detriment to the advantages of synthetic diamond.

One object of the invention is to propose a detector not having transitory de-trapping at shallow levels in the synthetic diamond.

Another object of the invention is to propose a detector which can neutralize the defects of the polycrystalline layer, to obtain a stabilized response of the detector in polycrystalline diamond.

Another object of the invention is to propose a detector comprising synthetic diamond which can be given industrial applicability, and is therefore of low cost.

Another object of the invention is to propose a detector of large surface area, or in mosaic.

Another object of the invention is to propose an integrated detector taking up little space.

Another object of the invention is to propose a detector which only generates very low disturbance of radiation.

The invention proposes a detector comprising a detector plate formed of a thin plate of synthetic diamond, and a heater or means for heating the detector plate, said heater or heating means comprising a thin heating plate compatible with the intended detection application, i.e., whose material has the same tissue-equivalence properties as the detector plate for medical applications, or the same transparency properties (low Z) as the detector plate for beam metrology applications. The thin heating plate advantageously consists of a material essentially containing carbon atoms.

The invention is advantageously completed by the following characteristics, either alone or in any technically possible combination:

the detector plate consists of polycrystalline diamond, doped or non-doped;

the material of the heating plate is a tissue-equivalent material for medical applications;

the material of the heating plate has a low atomic number for beam metrology applications;

the heating plate consists either of synthetic diamond, of doped or non-doped polycrystalline type, or of a material having carbon bonds, of carbon type in the form of amorphous diamond, nanocrystalline diamond or carbon in the form of amorphous polymer, or graphite;

the detector plate and the heating plate are in contact with each other;

the heating plate is separated from the detector plate by an electrically isolating intermediate plate whose material has an atomic number at least close to the atomic number of the material of the detector plate;

the material of the intermediate plate is a tissue-equivalent material for medical applications;

the material of the intermediate plate has a low atomic number for beam metrology applications;

the intermediate plate consists either of synthetic diamond, of doped or non-doped polycrystalline type, or of a material having carbon bonds of carbon type in the form of amorphous diamond, nanocrystalline diamond, or carbon in the form of amorphous polymer or graphite;

the heating plate extends above substantially the entire surface of the detector plate;

the detector plate and/or heating plate are doped;

the doping element is Boron, Phosphorus, Nitrogen or a combination of 2 or more thereof;

the detector comprises at least one measuring electrode in contact with the detector plate;

the detector comprises electrodes for passing a current in the heating plate; and

the electrodes are either of a synthetic diamond-based material, of polycrystalline type whether doped or not, or a material having carbon bonds of carbon type in the form of amorphous diamond, nanocrystalline diamond, carbon in the form of amorphous polymer, graphite, or containing a metal or metal alloy.

The invention also concerns a measuring device comprising said detector.

The invention also concerns a measurement method using said detector and a method for fabricating said detector.

### BRIEF DESCRIPTION OF THE FIGURES

Other characteristics, purposes and advantages of the invention will become apparent from the following description which is purely illustrative and non-limiting and is to be read with reference to the appended drawings in which:

FIGS. 1A to 1D schematically show a longitudinal section of a first manufacturing embodiment of a detector according to the invention;

FIGS. 2A to 2D schematically show a longitudinal section of a second manufacturing embodiment of a detector according to the invention;

FIGS. 3A to 3C show different possible positions of the electrodes on a detector plate in accordance with the invention;

FIG. 4 schematically shows a heating device of the heating plate; and

FIGS. 5A and 5B schematically show different configurations of electrodes on the plate surfaces.

In all the figures similar parts carry identical reference numbers.

### DETAILED DESCRIPTION

To overcome the problem of transitory de-trapping of shallow traps, in a synthetic diamond-based detector, one solution involves using the detector at a temperature at which it is possible to maintain a “stable” state of the populations trapped in the material.

Instead of maintaining the device at a low temperature in order to block the carriers trapped in occupied levels (a solution which naturally comes to mind) one method according to the invention, on the contrary, involves heating the detector to a few dozen degrees (e.g., between 50° C. and 150° C.). Such method of the invention thereby avoids having to use an installation with cryogenic equipment.

Recent studies on the physical parameters of the trap levels concerned have shown that the method of the invention is functional.

A detector must therefore be manufactured which is uniformly heated by a material which does not disturb either the detector diamond layer or the radiation to be detected.

To ensure the rise in temperature of the detector, conventional electric heating is not suitable as the advantages of diamond (i.e., low Z, tissue-equivalence, chemical inertia, etc.) would be cancelled if an additional material was used in the detector whose physical characteristics are far too remote from those of diamond.

For medical and detection applications, the detector is inserted in the beam but must not form a screen or disturb the beam. It is therefore not only the detection layer but also the entire detector which must not disturb radiation.

The invention therefore proposes a detector comprising a detector plate formed of a thin plate of synthetic diamond and a heater or means for heating the detector plate. The heater or heating means comprises a thin heating plate whose material is a tissue-equivalent material for medical applications, or has a low atomic number for beam metrology applications.

The material of the thin heating plate essentially consists of carbon atoms. In the remainder of the description by “material essentially consisting of carbon atoms” is meant a material whose chemical composition, irrespective of its crystalline or amorphous structure, almost exclusively contains carbon atoms. If other chemical components are present in the material, these are then residues or dopants. The material is therefore close to a “diamond” material.

This gives a material that is both heat conductive and transparent to the radiation to be detected. The absence of “non-diamond” materials in the vicinity of the detector means that beam measurement is not disturbed by foreign elements, whether for dose or other measurement.

Therefore the material of the heating plate may be diamond, preferably synthetic, or a material with carbon bonds such as carbon in the form of amorphous diamond for example or “Diamond Like Carbon” (DLC), nanocrystalline diamond, carbon in the form of amorphous polymer or “Polymer Like Carbon”, etc.

The material of the heating plate desirably has low resistivity and the injection of an electric current allows its heating by Joule effect.

Advantageously, the heating plate comprises a thin layer of doped diamond, doped with boron, phosphorus or nitrogen for example. Said doping imparts reduced resistivity to the heating plate with respect to the intrinsic material. It then becomes possible to cause an electric current to circulate in the heating plate allowing its rise in temperature.

It will be understood that the heating plate may be any layer of diamond or material with carbon bonds whose resistivity is reduced after special treatment.

A first embodiment of manufacture involves integrating into a detector, having a first detection plate in diamond, a second plate whose role is to enable heating of the detector. The coupling of this low resistivity heating plate to the diamond detector is ideally performed by stacking two layers of different resistivity during their synthesis. For example, a doped layer of a few dozen microns may be directly deposited on the intrinsic diamond layer used to detect particles or incident photons.

A second possible manufacturing embodiment involves using two separate layers, one of low resistivity for heating and the other of high resistivity for detection, and to place them in contact mechanically.

It may be desired to insert an intermediate layer between the two layers, whose purpose is to electrically insulate the detector—in which very low currents must remain measurable—from the heating part—in which high current densities may be necessary. The intermediate layer also consists of a tissue-equivalent material for medical applications, or has a low atomic number for beam metrology applications, so that it is non-disturbing.

The manufacture of possible embodiments of the detector is detailed below.

### First Embodiment and Manufacture

FIG. 1A shows that during a first step, on a substrate 1, synthetic diamond material 2 is caused to grow for the detection of radiation.

Diamond synthesis is made by Chemical Vapor Deposition (CVD), optionally plasma-assisted (Plasma Enhanced CVD (PECVD) of microwave type for example.

The synthesis technique for the diamond layer 2 is known to those skilled in the art and leads to obtaining a sample of polycrystalline diamond 2 if the synthesis takes place on a substrate 1 different to diamond (hetero-epitaxy), and to a single crystalline sample 2 if homo-epitaxy is used.

The remainder of this description applies to hetero-epitaxy on a silicon substrate 1, the principle being the same for homo-epitaxy, with a restriction however regarding the size of the growth substrate 1 and hence of the end detector.

The deposit conditions for obtaining detecting diamond material are referenced in the literature. They are particular to each reactor and optimized to obtain a material of electronic quality.

In a conventional PECVD reactor, these conditions typically range between 1.5 kW and 5 kW microwave power, 70 torr to 125 torr pressure in the deposit chamber, and 750 to 950° C. for the depositing temperature. The microwave plasma is obtained by separating a gaseous mixture of hydrogen and methane with the optional addition of oxygen.

The thickness of the layer 2 forming the detector plate obtained varies between 20 and 500 microns depending upon intended applications (i.e., detection of alpha particles, X-rays, etc.) on whole substrates 1, measuring 2 to 5 inches or pre-cut samples.

After synthesis of the plate 2, the sample can be removed from the first growth reactor and transferred to a reactor allowing the material of plate 2 to be doped. Preferably, the plate 2 is doped with boron, phosphorus, or nitrogen for example. The doping step of the detector plate 2 is optional.

The synthesis of an intermediate plate 3 in the form of a thin layer superimposed over plate 2, is performed during a second step in the doping reactor and without the intentional incorporation of impurities. The thickness of layer 3 is typically a few microns. The material of the intermediate plate 3 obtained is intrinsic with residual dopant impurities.

During a third step, the synthesis of the heating plate 4 in the form of a thin layer is performed by CVD with the intentional incorporation of impurities by re-growth on the intermediate layer 3. The thickness of layer 4 is typically around 10 microns. The impurities may be boron atoms for example in variable concentration, e.g., 10¹⁵ to 10²¹ at/cm³. This doping technique reported in the literature makes it possible to obtain layers of variable resistivity according to the concentration of incorporated dopants. The material of plate 4 is preferably doped, but may also be non-doped.

The stacking of the materials obtained after the three successive steps is shown FIG. 1A. Plate 3 acts as insulator between the detector plate 2 and the heating plate 4. The resistivity of plate 3 is greater than that of plate 4. The presence of an intermediate layer 3 is optional. The depositing of the heating plate 4 can be performed directly in the form of a layer on the detector plate 2.

During a fourth step shown FIG. 1B, the silicon substrate 1 used as growth support during the first step is removed. The substrate 1 can be removed by chemical etching using a HF/HNO₃ mixture. The chemical composition of the mixture allows selective etching of the growth substrate 1 leaving intact layers 2, 3 and 4 obtained during the first three steps described above.

FIG. 1C shows that electrodes 10 and 20, allowing polarization of plate 2 and the measurement of a signal, can be vapor deposited during a fifth step on the material of plate 2.

FIG. 1D shows that contacts 30 and 40 are also made during a sixth step on an upper surface of the doped plate 4. Contacts 30 and 40 are used to power heating.

The geometry, thickness of contacts 10, 20, 30 and 40 and the material used for contacts 10, 20, 30 and 40 are adapted to the intended applications.

For example, for medical applications, contacts 10, 20, 30 and 40 are desirably in carbon, a material with carbon bonds or a tissue-equivalent material, so as not to lose the advantages of diamond in the detector plate 2. The electrodes 10, 20, 30 and 40 are desirably of synthetic diamond for example, of polycrystalline type whether doped or not, or a material containing carbon bonds such as carbon in the form of amorphous diamond or “Diamond Like Carbon” (DLC), nanocrystalline diamond, carbon in the form of amorphous polymer or “Polymer Like Carbon”, or graphite.

For non-medical applications, e.g., beam control, it may be preferred to vapor deposit metals or metal alloys whose contact with the diamond of plate 4 and plate 2 is ohmic, by adapting the vapor deposited thickness according to needs. The metals which may be used are gold or a Ti/Pt/Au alloy for example. Mention may be made for example of vapor depositing 20 nm gold to obtain a semi-transparent layer.

The depositing of contacts 10, 20, 30 and 40 is performed according to required accuracy, through metal masks or by lithography. Vapor deposit techniques for contacts are part of general knowledge, and the techniques and materials are largely reported in the literature. The depositing of contacts 10, 20, 30 and 40 may be made by vapor deposit under Joule effect, or using an electron gun or any other technique known to persons skilled in the art. FIGS. 1C and 1D show a possible configuration of contacts 10, 20, 30 and 40, other polarization and heating configurations are described in more detail below.

### Second Embodiment and Manufacture

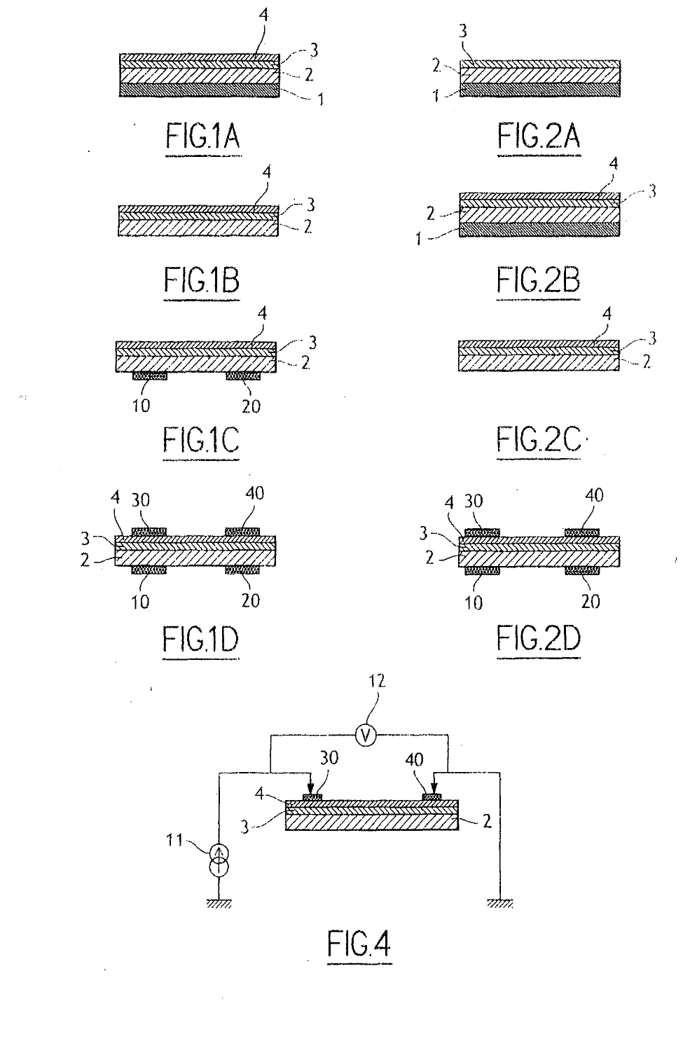

FIG. 2A shows that, during a first step, synthetic diamond material 2 is grown on a substrate 1, for the detection of radiation. This step is identical to the first step described previously.

During a second optional step, an intermediate layer 3 may be grown on layer 2. This layer 3 plays the same role as the layer described in the previous second step and may be obtained under the same conditions. Layer 3 may also be obtained in the intrinsic growth reactor. After the synthesis of layers 2 and 3, the sample is removed from the growth reactor to start assembly of the device.

During a third step, shown FIG. 2B, the heating plate 4 is assembled.

Plate 4, enabling a rise in temperature of plate 2, may more generally be of a diamond material which has been treated to reduce its resistivity, a material with carbon bonds (diamond obtained by other growth techniques, DLC, nanocrystalline diamond, polymer like carbon, etc.) or a material with low resistivity and tissue equivalence for medical applications, or having a low Z for radiation beam metrology applications.

The plate 4 may be assembled mechanically on the previous layers 2 and 3. This may entail mere contact, bonding, molecular bonding, etc.

The use of mechanical coupling between the detector 2 and heating 4 plates—optionally via an intermediate plate 3—has the advantage of allowing the association of materials whose direct growth of one layer on another is not possible. The range of choice of materials for the different plates 2, 3 and 4 is therefore much wider and can be adapted to intended applications. On the other hand, mechanical assembly may offer lesser heating homogeneity than a detector fabricated by direct growth of layers.

The depositing of contacts 10, 20, 30 and 40 shown in FIG. 2D is identical to the depositing performed in the first embodiment and described with reference to FIGS. 1C and 1D.

Functioning

A distinction can be made between two geometrically separate parts in the functioning of the detector. Firstly there is the detection of radiation by the optimized intrinsic diamond layer 2, and secondly there is its rise in temperature by means of the heating plate 4.

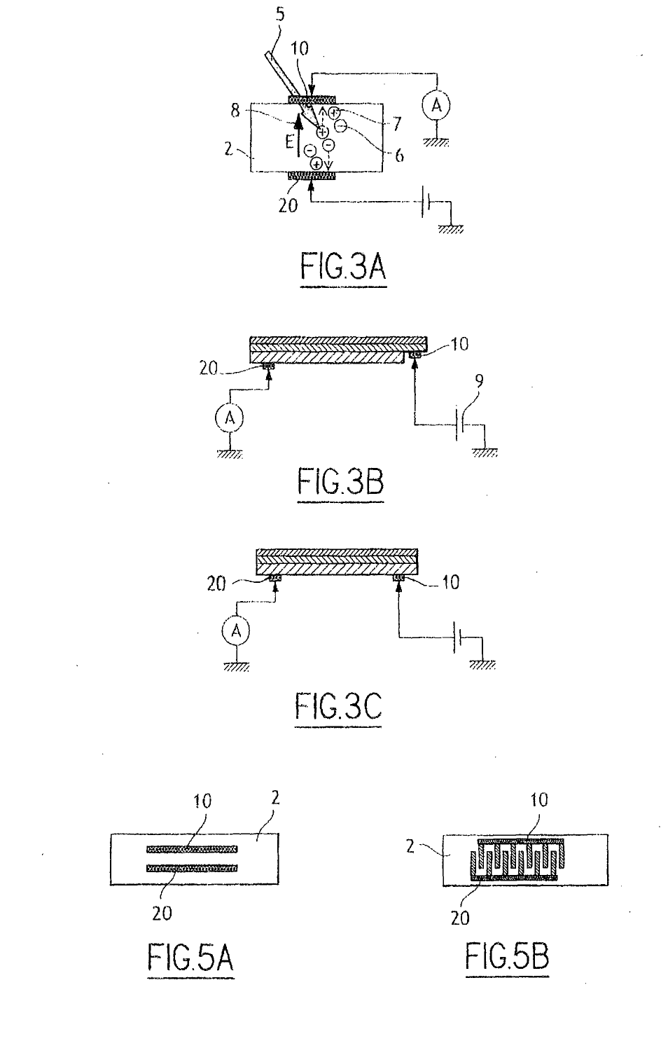

Radiation detection is based on the principle of an ionizing chamber. FIG. 3A shows that the ionizing radiation 5 interacts with the diamond material of plate 2 and creates free carriers of electron 6 and hole 7 type which, under the action of an electric field 8 applied to the sample, are collected at the electrodes 10 and 20 giving rise to a measurable electric signal.

Diamond allows this functioning mode owing to the width of its bandgap at ambient temperature (5.5 eV).

FIG. 3A shows that electrodes 10 and 20 can be vapor deposited on each surface of diamond plate 2.

FIGS. 1C, 1D, 2D and 3C show that the electrodes 10 and 20 may be on the same surface of the diamond plate 2. FIG. 5A shows that the electrodes 10 and 20 may be in coplanar contact configuration on the same surface of the diamond plate 2, and FIG. 5B shows that the electrodes 10 and 20 may be interdigitated on the same surface of the diamond plate 2.

According to one variant, use is made of the fact that the intermediate layer 3 can act as rear contact. FIG. 3B therefore shows that a conductive deposit 10 is vapor deposited on layer 3 to allow application of a voltage to plate 2 by means 9 forming a voltage source for example. The signal created by the radiation is then recorded by means of the electrode 20 on the front face of plate 2.

Two functioning modes can be used: the counting mode and the current mode. These two functioning modes are known in instrumentation.

FIG. 4 shows a device allowing the plate 2 to be heated by means of the thin plate 4 of low resistivity.

Means 11 forming a current source for example make it possible to produce a current (of 1 mA to 10 mA) and to cause it to pass through layer 4 between the electrodes 30 and 40 on the surface of layer 4. Passing of the current allows the temperature of layer 4 to be increased. Heating due to the circulation of electric carriers is sensitive and can be easily controlled by adjusting current density.

The operating temperature of the detector plate 2 lies between 50° C. and 150° C.

Calibration in relation to the doping level of layer 4, and to the thickness and geometry of the detector allows determination of the current values needed for the desired rise in temperature.

Similarly, calibration may also allow measurement of residual voltage via means 12 forming a voltmeter and connected between the electrodes 30 and 40 when measuring the current, in order to know the instant resistivity of the heating plate 4 and hence to determine its temperature.

To prevent the heating current from disturbing the detector's signal, the intermediate diamond layer 3 described in the previous devices is used. With the intermediate layer 3 it is possible to separate the heating current from the detection current.

The electrodes 30 and 40 may be on the same surface of the heating plate 4. As is the case for electrodes 10 and 20, the electrodes 30 and 40 may have a coplanar contact configuration or be interdigitated on the same surface of the heating plate 4.

The functioning of the detector in the radiation detection mode requires prior calibrations.

Before use, the detector plate 2 is characterized under radiation. The detector's response is analyzed in relation to the measurement temperature and in relation to irradiation records. In this way it is possible to study the performance of the detection device in relation to trap occupancy. The optimal functioning temperature of the detector, namely at which the measurement temperature does not affect stability is thus determined.

The heating plate 4 is also characterized before use of the device by controlling the current level in the heating material, in order to obtain the set temperature defined according to preceding characterizations.

After each use, the detector can be reset to zero by merely heating the detector a very short time to high temperature (higher than 200° C. and typically up to 400° C.). Then, before first use, prior radiation of the detector is performed to ensure the same trap occupancy state at all times. The radiation dose necessary for equilibrium of the detector is determined by prior characterization.

The device ready to function can be supplemented by a calibration record sheet and directions for use giving:

the dose necessary for pre-radiation;

the optimal functioning temperature, also called “set temperature”;

the current level to be applied in the heating layer 4 to obtain the set temperature;

the temperature required for resetting the device to zero (emptying trap levels) also called “cleaning temperature”; and

the current level to be applied in the heating layer 4 to obtain the cleaning temperature.

The invention is advantageously used for the detection of radiation in radiotherapy and for the measurement of beam doses in X-ray beam monitors and positioners. In radiotherapy in particular, the device enables the measurement of beam dose and dose rate before patient irradiation, at a heating temperature which is not harmful for the patient. Since the device can be entirely designed of a material at least close to tissue-equivalence, the correction factors usually required are not necessary, and the simplification and accuracy of measurement are thereby increased. The device may comprise means for forming a four-quadrant detector.

1. A detector comprising a detector plate formed of a thin plate of synthetic diamond, and a heater for heating the detector plate, said heater comprising a thin heating plate whose material essentially consists of carbon atoms.

2. The detector according to claim 1, wherein the detector plate consists of polycrystalline diamond, whether doped or not.

3. The detector according to claim 1, wherein the heating plate consists either of synthetic diamond of doped or non-doped polycrystalline type, or of a material having carbon bonds, of carbon type in the form of amorphous diamond, nanocrystalline diamond, carbon in the form of amorphous polymer, or graphite.

4. The detector according to claim 1, wherein the detector plate and the heating plate are in contact with one another.

5. The detector according to claim 1, wherein the heating plate is separated from the detector plate by an electrically insulating intermediate plate and whose material essentially consists of carbon atoms.

6. The detector according to claim 5, wherein the intermediate plate consists of either synthetic diamond, of doped or non-doped polycrystalline type, or of a material having carbon atoms, of carbon type in the form of amorphous diamond, nanocrystalline diamond, carbon in the form of amorphous polymer, or graphite.

7. The detector according to claim 1, wherein the heating plate extends above substantially the entire surface of the detector plate.

8. The detector according to claim 1, wherein the detector plate and/or the heating plate are doped.

9. The detector according to claim 8, wherein the doping element is selected from the group consisting of Boron, Phosphorus, Nitrogen or a combination thereof.

10. The detector according to claim 1, additionally comprising at least one measuring electrode in contact with the detector plate.

11. The detector according to claim 1, additionally comprising electrodes for passing a current in the heating plate.

12. The detector according to claim 11, wherein the electrodes are either of a synthetic diamond-based material, of doped or non-doped polycrystalline type, or a material having carbon bonds, of carbon type in the form of amorphous diamond, nanocrystalline diamond, carbon in the form of amorphous polymer, graphite, or containing a metal or metal alloy.

13. The detector according to claim 1, for radiation beam metrology wherein the detector plate, heating plate and intermediate plate are each of a material having an atomic number of 8 or less.

14. The detector according to claim 1, for medical dosimetry wherein the detector plate, the heating plate and the intermediate plate are each of tissue-equivalent materials.

15. An imaging device, comprising at least one detector according to claim 1.

16. The device according to claim 15, comprising means for forming a four-quadrant detector.

17. A measurement method using a detector plate formed of a thin plate of synthetic diamond, comprising heating the detector plate with a heater comprising a thin heating plate whose material essentially consists of carbon atoms.

18. The method according to claim 17, wherein at a time of measurement the detector plate is heated to an operating temperature of between 50° C. and 150° C.

19. The method according to claim 17, wherein the detector plate is heated to a zero resetting temperature of more than 200° C. between two measurements.

20. A method for manufacturing a detector comprising a detector plate formed of a thin plate of synthetic diamond, the method comprising coupling a thin plate to heat the detector plate with said detector plate and the material of the heating plate essentially consisting of carbon atoms.

21. The method according to claim 20, wherein said coupling comprises depositing the heating plate in the form of a thin layer by chemical vapor deposit.

22. The method according to claim 20, wherein the coupling of the heating plate above the detector plate is mechanical.

23. The method according to claim 20, wherein the coupling is via an intermediate plate whose material essentially consists of carbon atoms.

24. The method according to claim 23, comprising depositing the intermediate plate on the detector plate in the form of a thin layer by chemical vapor deposit.

25. The method according to claim 20, additionally comprising depositing electrodes on the detector plate and the heating plate.
